(19) United States
(12) Patent Application Publication
(10) Pub. No.: US 2025/0054911 A1
(43) Pub. Date: Feb. 13, 2025

(54) SYSTEMS AND METHODS FOR THREE-DIMENSIONAL MEMORY STACKING

(71) Applicant: Meta Platforms Technologies, LLC, Menlo Park, CA (US)

(72) Inventors: Huichu Liu, Santa Clara, CA (US); Simon James Hollis, Redmond, WA (US); Fan Wu, Redwood City, CA (US); Huseyin Ekin Sumbul, San Francisco, CA (US); Lita Yang, Sunnyvale, CA (US); Edith Dallard, San Mateo, CA (US)

(21) Appl. No.: 18/391,018

(22) Filed: Dec. 20, 2023

Related U.S. Application Data
(60) Provisional application No. 63/518,044, filed on Aug. 7, 2023.

(51) Int. Cl. H01L 25/065; H01L 23/00; H10B 80/00

(52) U.S. Cl. CPC H01L 25/0657; H01L 24/08; H01L 24/80; H10B 80/00; H01L 2224/08145; H01L 2224/80895; H01L 2224/80896; H01L 2225/06541; H01L 2924/1431; H01L 2924/1437

(57) ABSTRACT

A method for three-dimensional memory stacking may include providing a logic die including a circuit and a memory, providing a memory die including an additional memory having a same footprint as the circuit and memory in the logic die, and stacking the logic die and the memory die three-dimensionally with die-to-die data communication between the circuit and the additional memory by face-to-face hybrid bonds. Various other methods, systems, and computer-readable media are also disclosed.

### CROSS REFERENCE TO RELATED APPLICATIONS

This application claims the benefit of U.S. Provisional Application No. 63/518,044, filed Aug. 7, 2023, the disclosure of which is incorporated, in its entirety, by this reference.

### BRIEF DESCRIPTION OF DRAWINGS

The accompanying drawings illustrate a number of exemplary embodiments and are a part of the specification. Together with the following description, these drawings demonstrate and explain various principles of the present disclosure.

FIG. 1 is a flow diagram of an exemplary method for three-dimensional memory stacking.

FIG. 2 is an illustration of an exemplary stacked neural network accelerator in two dies.

FIG. 3 is an illustration of an exemplary stacked neural network accelerator in two dies.

FIG. 4 is an illustration of an exemplary stacked neural network accelerator in a two die system.

FIG. 5 is an illustration of an exemplary multi-tier three-dimensional stacked neural network accelerator.

FIG. 6 is an illustration of different configuration settings at runtime to configure a partition of activation and weight static random access memories.

FIG. 7 is an illustration of different configuration settings at runtime to configure a partition of activation and weight static random access memories.

FIG. 8 is an illustration of exemplary augmented-reality glasses that may be used in connection with embodiments of this disclosure.

FIG. 9 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Augmented reality and virtual reality glasses (e.g., VR headsets, AR glasses, etc.) often benefit from inclusion of neural network accelerators. A neural network (NN) accelerator is a processor that is optimized specifically to handle neural network workloads. Such accelerators cluster and classify data efficiently and at a fast rate. Various types of workloads benefit from different configurations of sizes of activation memory and weight memory, leading to multiple, different neural network accelerators being used for different types of workloads. NN accelerators may be implemented in AR/VR glasses and process images rendered to one or more display devices. However, AR/VR glasses have limited area for system on chip (SoC) accelerators, and using multiple accelerators increases costs.

The present disclosure is generally directed to systems and methods of three-dimensional (3D) memory stacking. For example, the disclosed systems and methods may three-dimensionally stack a logic die including a circuit (e.g., neural network accelerator) and a memory (e.g., local static random access memory (SRAM)) with a memory die including an additional memory (e.g., SRAM) having a same footprint as the circuit and memory in the logic die. The disclosed systems and methods may also perform die-to-die data communication between the circuit and the additional memory by face-to-face hybrid bonds. Additionally, this die-to-die data communication may occur by a first connection channel having a first bandwidth and a second connection channel having a second bandwidth lower than the first bandwidth. Accesses of the first connection channel and the second connection channel to memory banks of the additional memory may be controlled by a configuration register that governs a partition of the additional memory. In addition to configuring the sizes of the additional memory allocated to the data communication channels, the configuration register may govern storage of data types (e.g., weights, activations, etc.) in partitions of the additional memory (e.g., by triggering storage of weights and activations in different partitions). Further, the circuit may be configured to set the configuration register to select the partition and two or more data types based on pre-profiled characteristics of a workload. To accommodate workloads requiring more memory, an additional memory die having a same footprint as the circuit and memory in the logic die may be stacked three-dimensionally with die-to-die data communication between the circuit and the further memory by face-to-back through silicon via. In this way, a single neural network accelerator may be configurable for different types of workloads, thus meeting form factor requirements of AR/VR glasses and reducing costs.

Features from any of the embodiments described herein may be used in combination with one another in accordance with the general principles described herein. These and other embodiments, features, and advantages will be more fully understood upon reading the following detailed description in conjunction with the accompanying drawings and claims.

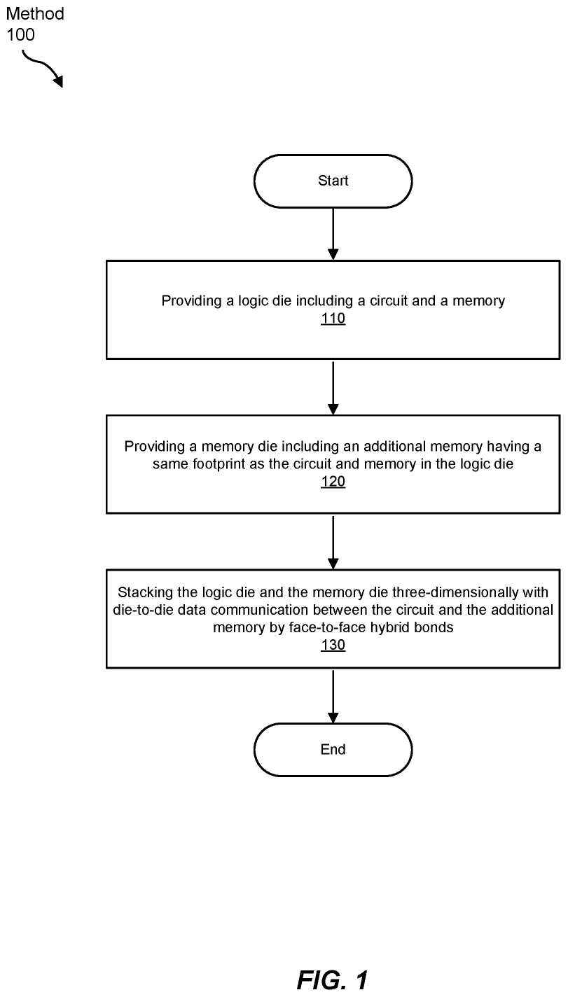

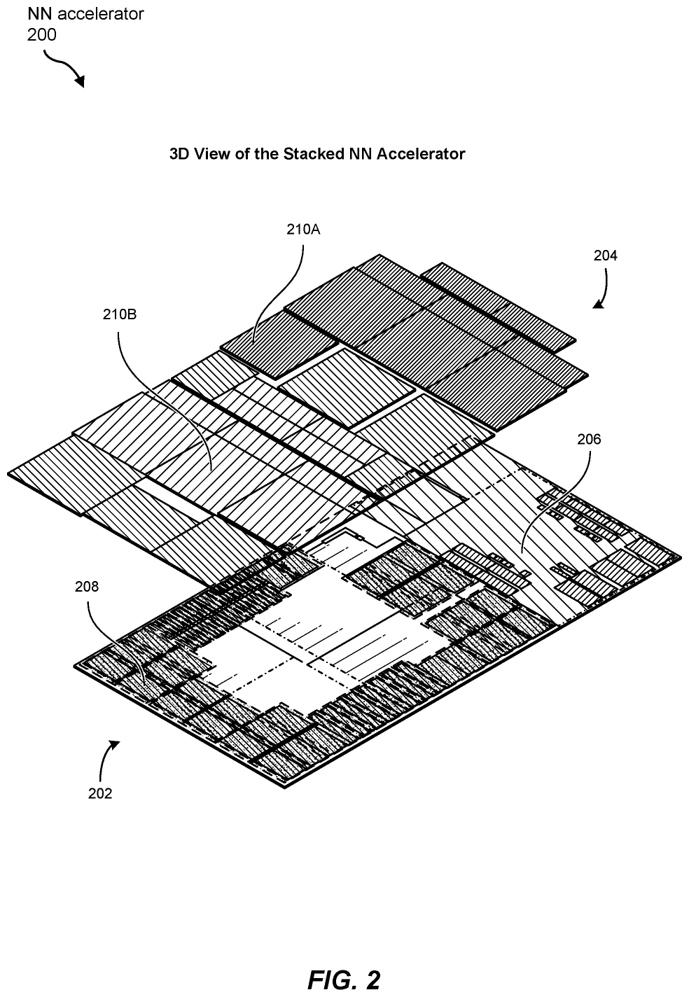

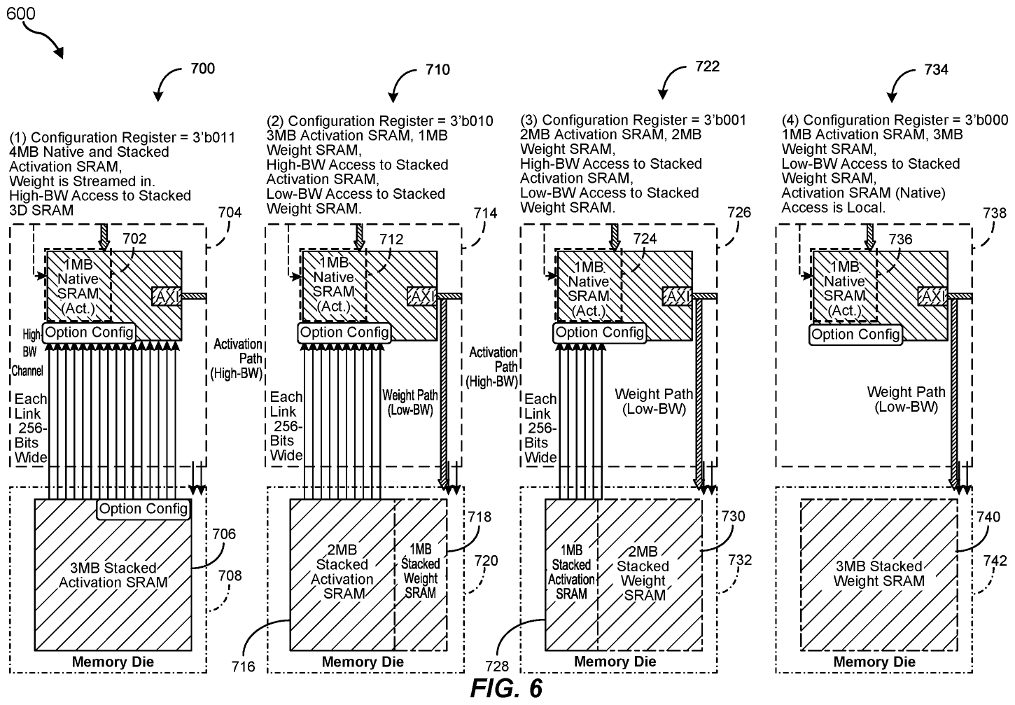

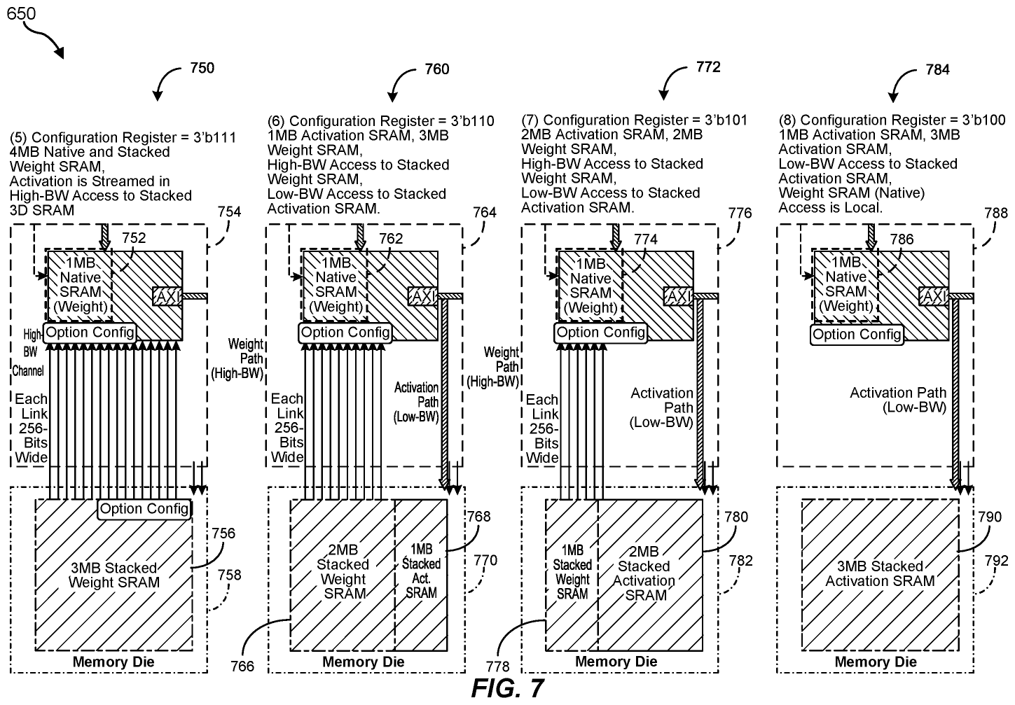

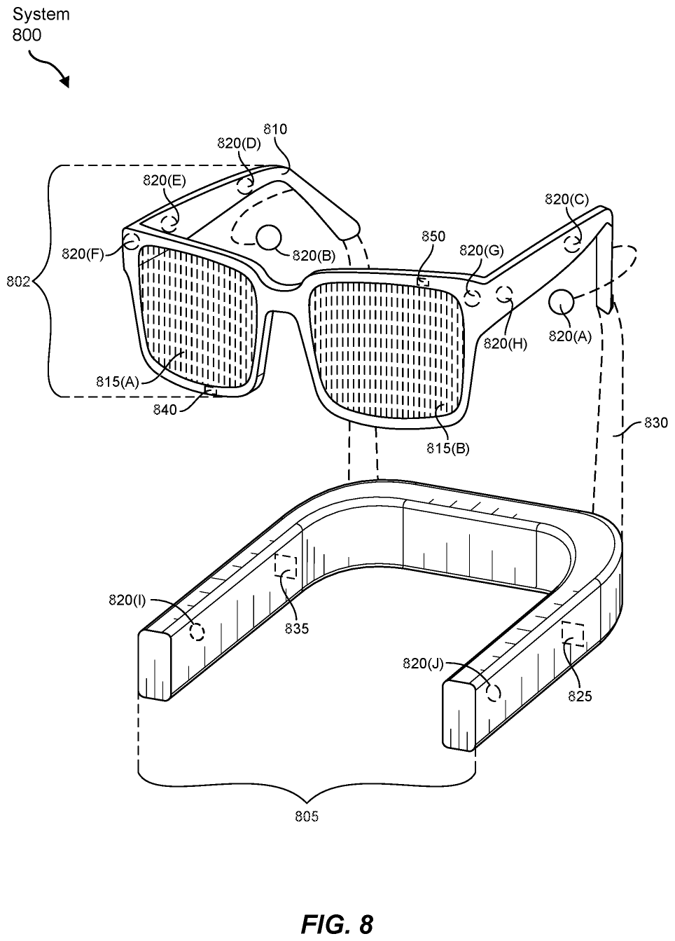

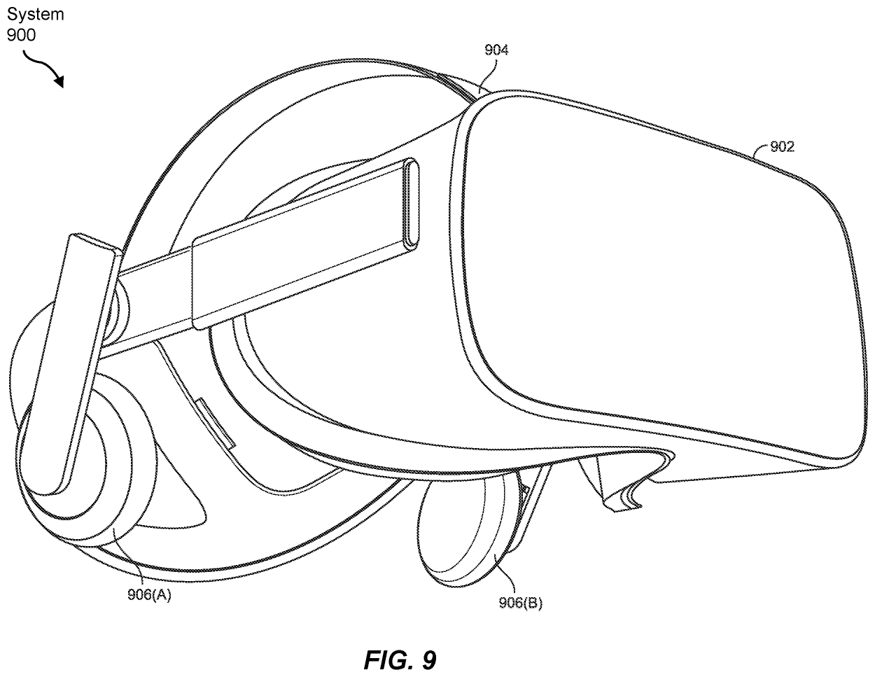

The following will provide, with reference to FIG. 1, detailed descriptions of exemplary methods for three-dimensional memory stacking. Detailed descriptions of exemplary stacked neural network accelerators are also provided with reference to FIGS. 2-5. Additionally, detailed descriptions of different configuration settings at runtime to configure a partition of activation and weight static random access memories are provided with reference to FIGS. 6 and 7. Further, detailed descriptions of exemplary augmented-reality glasses and virtual-reality headsets are provided with reference to FIGS. 8 and 9.

FIG. 1 is a flow diagram of an exemplary method 100 for three-dimensional memory stacking. Beginning at step 110, method 100 may include providing a logic die. For example, step 110 may include providing a logic die including a circuit and a memory.

The term “die,” as used herein, may generally refer to a thin piece of silicon. For example, and without limitation, a die may include a thin piece of silicon on which components, such as transistors, diodes, resistors, and other components, are housed to fabricate a functional electronic circuit. In this context, a “logic die” may correspond to a die that contains a majority of the logic components (e.g., transistors) of the electronic circuit of a semiconductor device. In contrast, a “memory die” may correspond to a die that contains a majority of the memory components (e.g., SRAM, DRAM, etc.) of the electronic circuit of a semiconductor device.

The term “circuit,” as used herein, may generally refer to a complete circular path through which electricity flows. For example, and without limitation, a simple circuit may include a current source, conductors, and a load. The term circuit can be used in a general sense to refer to any fixed path through which electricity, data, or a signal can travel. One example type of circuit may be a neural network accelerator.

The term “memory,” as used herein, may generally refer to an electronic holding place for instructions and/or data used by a computer processor to perform computing functions. For example, and without limitation, a memory may correspond to MOS memory, volatile memory, non-volatile memory, and/or semi-volatile memory. Example types of memory may include static random access memory (SRAM) and/or dynamic access random memory (DRAM).

Step 110 may be performed in a variety of ways. In one example, the circuit of the logic die provided in step 110 may correspond to a processor of a neural network accelerator. In some of these examples, the circuit of the logic die provided in step 110 may have a configuration register or portion thereof that may control partitions of additional memory and/or storage of data types therein (e.g., activations, weights, etc.). Additionally or alternatively, the memory of the logic die provided in step 110 may include static random access memory (SRAM). In some of these examples, the memory of the logic die provided in step 110 may include native SRAM (e.g., a plurality of one megabyte SRAMs).

At step 120, method 100 may include providing a memory die. For example, step 120 may include providing a memory die including an additional memory having a same footprint as the circuit and memory in the logic die.

The term “footprint,” as used herein, may generally refer to a land pattern of a component on a printed circuit board. For example, and without limitation, a footprint may correspond to a region in a which a component will be soldered in forming a physical interface between the board and the component. In this context, footprint may correspond to an area of a semiconductor device in two dimensions.

Step 120 may be performed in a variety of ways. In one example, the additional memory of the memory die provided in step 120 may include SRAM. In some of these examples, the memory of the logic die provided in step 110 may include memory banks of different sizes (e.g., one or more one megabyte SRAMs and one or more two megabyte SRAMs). In some of these examples, the memory of the logic die provided in step 110 may have a configurable partition (e.g., a configuration register or portion thereof). In another example, step 120 may include providing an additional memory die including a further memory having a same footprint as the circuit and memory in the logic die. In various examples, the further memory may have any of or all of the features exhibited by the memory of the logic die provided in step 110 and/or the additional memory of the memory die provided in step 120.

At step 130, method 100 may include stacking the logic die and the memory die. For example, step 130 may include stacking the logic die and the memory die three-dimensionally with die-to-die data communication between the circuit and the additional memory by face-to-face hybrid bonds.

The term “stacking,” as used herein, may generally refer to vertically arranging two or more integrated circuit dies one atop another. For example, and without limitation, multiple integrated circuits may be stacked vertically using, for example, through silicon via and/or copper to copper (Cu—Cu) connections so that they behave as a single device to achieve performance improvements at reduced power and smaller footprint compared to convention two-dimensional processes.

The term “die-to-die data communication,” as used herein, may generally refer to a data interface between dies of a semiconductor device, for example, and without limitation, die-to-die data communication may be achieved using through silicon via, wires, direct bonding, hybrid bonding, etc.

The term “face-to-face,” as used herein, may generally refer to a bonding style in three-dimensional integrated circuits (3D ICs). For example, and without limitation, face-to-face bonding may bond integrated circuits by using the top-metals (e.g., faces) of two integrated circuits as the bonding sides when stacking the two integrated circuits. In contrast, face-to-back bonding may bond integrated circuits by using the top-metal (e.g., face) of only one of two integrated circuits as the bonding side when stacking the two integrated circuits.

The term “hybrid bonds,” as used herein, may generally refer to an extremely fine pith Cu—Cu interconnect between stacked dies. For example, and without limitation, hybrid bonding may include stacking one die atop another die with extremely fine pitch Cu—Cu interconnect used to provide the connection between these dies.

Step 130 may be performed in a variety of ways. In one example, the die-to-die data communication by the face-to-face hybrid bonds may occur by a first connection channel having a first bandwidth and a second connection channel having a second bandwidth lower than the first bandwidth. In some of these implementations, accesses of the first connection channel and the second connection channel to memory banks of the additional memory may be controlled by a configuration register that governs a partition of the additional memory, and the configuration register may govern storage of data types in partitions of the additional memory. In some of these implementations, the circuit may correspond to a processor of a neural network accelerator and the configuration register may trigger storage of weights in a first partition of the additional memory and storage of activations in a second partition of the additional memory. Alternatively or additionally, the circuit may be configured to set the configuration register to select the partition and two or more data types based on pre-profiled characteristics of a workload. Alternatively or additionally, the second connection channel may be connected to top input-output ports of the circuit through a protocol managed interface, the first connection channel may be connected to internal wires of the circuit through local three-dimensional wires, and/or the face-to-face hybrid bonds may be positioned directly atop a macro of the additional memory. In another example, step 130 may include stacking the logic die and the additional memory die three-dimensionally with die-to-die data communication between the circuit and the further memory by face-to-back through silicon via.

Implementations of the disclosed systems and methods may include a dataflow-aware, workload adaptable 3D NN accelerator employing by an advance 3D stacked memory architecture to increase on-device memory capacity while maintaining a same footprint (e.g., small form factor). A partition of the additional memory (e.g., SRAM) may be configurable in terms of data type partition (e.g., weights and activations) based on a best scheduling scheme of the workload to take advantage of a best energy efficiency).

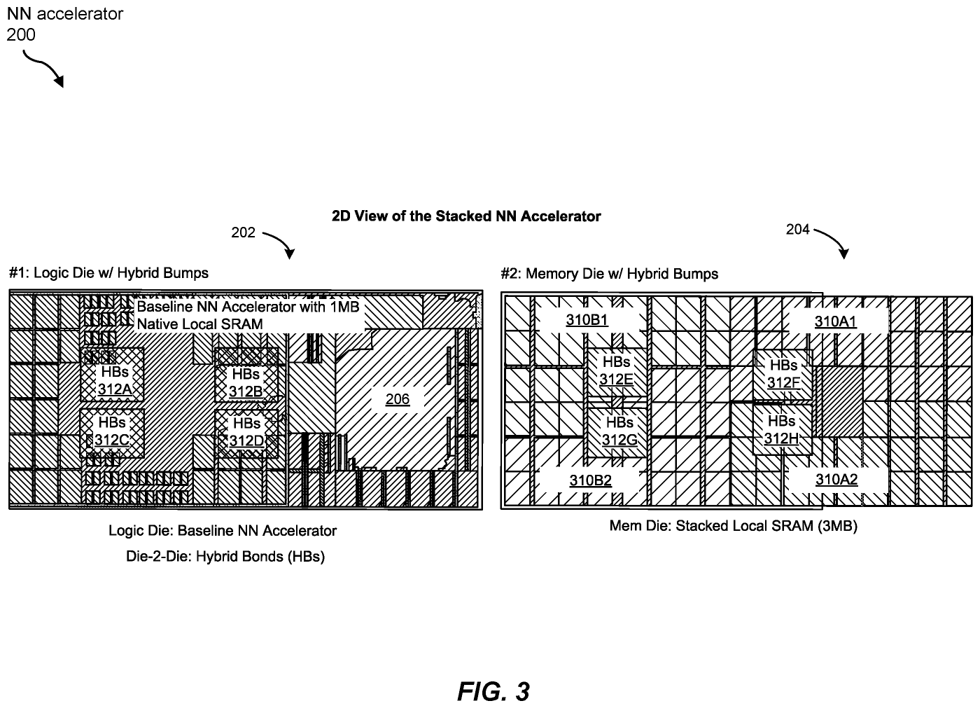

FIGS. 2 and 3 illustrate an exemplary stacked neural network (NN) accelerator 200 in two dies. For example, the NN accelerator 200 (e.g., including a processing element (PE) array and local SRAMs) may be partitioned into two dies, such as a logic die 202 and a memory die 204. The logic die 202 may have a native accelerator 206 as in a conventional augmented reality system on chip (AR SoC) and local SRAMs 208 (e.g., one megabyte native), while the memory die 204 may have additional SRAMs that have a same footprint as the accelerator 206 in the logic die. The additional SRAMS may be of different sizes, such as one or more one megabyte SRAMS 210A and one or more two megabyte SRAMS 210B. The two dies may be face-to-face bonded using hybrid bonds 312A-312H (e.g., only). These bonds 312A-312H may be directly placed on top of the SRAM macro; hence there may be no area overhead. For example, the bonds 312E-312F may be distributed over different SRAM memory banks 310A1, 310A2, 310B1 and 310B2.

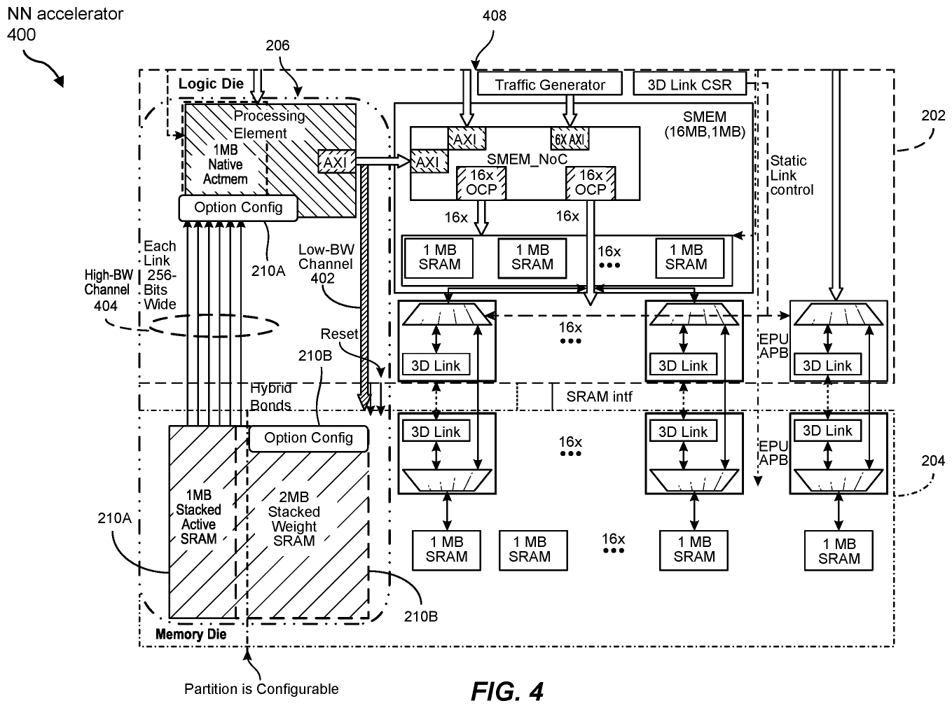

FIG. 4 illustrates an exemplary stacked neural network accelerator 400 in a two die system that may show in greater detail the connections of NN accelerator 200 detailed with reference to FIGS. 2 and 3. For example, connections between the logic die accelerator 206 and memory die SRAMs 210A and 210B may be through two channels, such as a low bandwidth (BW) connection channel 402 and high BW connection channel 404. The low bandwidth channel 402 may be connected to top input-output (IO) ports 408 of the accelerator 206 through a protocol managed interface (e.g., Advanced extensible Interface (AXI)) and this channel may have a BW of 16B/cycle. The high bandwidth channel 404 may be connected to the accelerator internal wires (e.g., shorter connection to the compute arrays) through local 3D wires, and this channel 404 may have a BW of 128B/cycle. Both the high BW channel 404 and the low BW channel 402 may access the stacked SRAM 210A and 210B on the memory die. The high BW-channel 404 may have low latency (e.g., 2-3 cycles) to access the stacked SRAM 210A and 210B, while the low-BW channel 402 may encounter higher latency (e.g., 6-10 cycles) to access the stacked SRAM 210A and 210B.

In some implementations, the stacked SRAM may store two different data types (e.g., activations and weights), and this storage may also be controlled by a bit in one or more configuration registers 410A and 410B along with the partition. Thus, a configuration register may be implemented as two separate registers 410A and 410B that may be programmed together to provide a common understanding of the memory space between the memories found on the logic die and the memory die. For example, when the configuration registers 410A and 410B are set to one, the high-BW partition may store activations while the low-BW partition stores the weights, and vice versa when the configuration registers 410A and 410B are set to zero. Additional examples of use of configuration registers 410A and 410B are detailed later with reference to FIGS. 6 and 7.

The accesses of the high-BW channel 404 and low-BW channel 402 to SRAM banks may be multiplexed to the ports of the SRAMs and controlled by a configuration register. The configuration register may control the partition of the stacked SRAMs (e.g., in terms of size of memory (e.g., numbers of memory banks)) allocated for access by the channels.

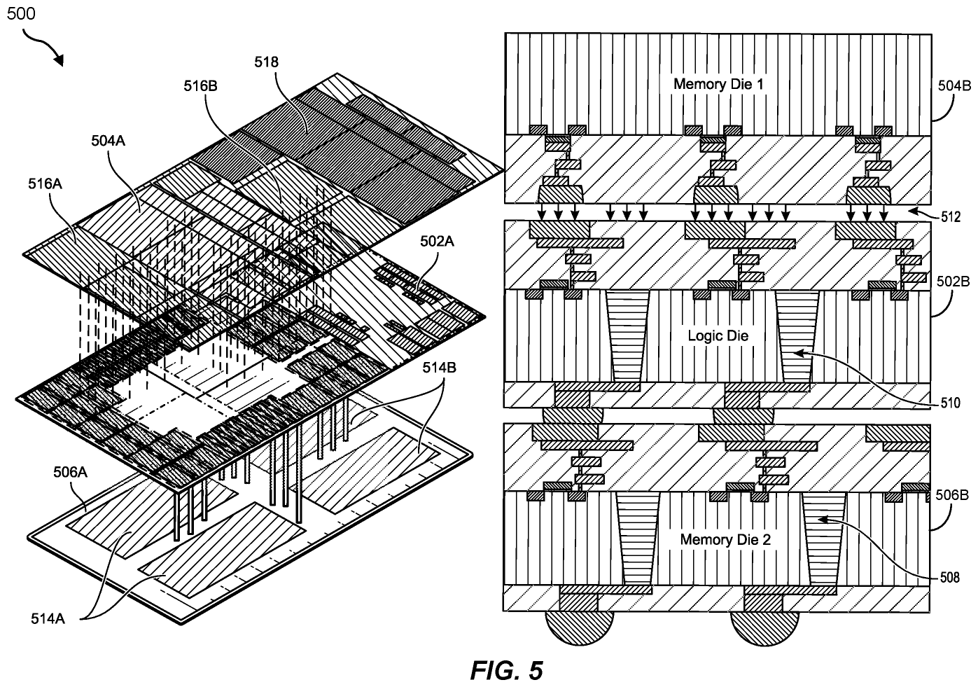

FIG. 5 illustrates an exemplary multi-tier three-dimensional stacked neural network accelerator 500. For example, NN accelerator 500 may include a logic die 502A and 502B, a memory die 504A and 504B, and an additional memory die 506A and 506B. The logic die 502A and 502B and the memory die 504A and 504B may have any of or all of the features exhibited by the logic die 202 and the memory die 204 of FIGS. 2-4. For example, the memory die may include low BW memory 516A and 516B and high BW memory 518. The additional memory die 506A and 506B may have further memory 514A and 514B having a same footprint as the circuit and memory in the logic die 502A and 502B. In various examples, the further memory 514A and 514B may have any of or all of the features exhibited by the memory of the logic die 202 of FIGS. 2-4 and/or the additional memory of the memory die 204 of FIGS. 2-4.

As shown in FIG. 5, the disclosed systems and methods may allow multi-tier die stacking to continue adding low-BW memories 514A and 514B to the accelerator and further increase the memory capacity. For example, a three-tier semiconductor device may stack the logic die 502A and 502B and a first memory die 504A and 504B face-to-face, and stack the logic die 502A and 502B and a second memory die 506A and 506B face-to-back by hybrid bonds 512. Different from face-to-face bonding, the second memory die 506A and 506B may use through silicon via 508 (TSV) to connect to the logic die 502A and 502B with face-to-back stacking via 510. Since TSV require additional area, the BW to the accelerator for the second memory die 506A and 506B may be relatively lower than the high-BW channel in the first memory die 504A and 504B. The logic die 502A and 502B may have SRAM (e.g., lower dynamic power, less dense), custom dynamic random access memory (DRAM) (e.g., lower leakage power, high density), or other non-volatile memories based on the system requirements.

FIGS. 6 and 7 illustrate different configuration settings 600 and 650 at runtime to configure a partition of activation and weight static random access memories. During runtime, for example, the compiler or firmware may set the configuration register to select the stacked SRAM partition as well as the data types based on pre-profiled characteristics of the workload. For example, if the workload prefers activation stationary, the configuration may be set to use the local SRAM (e.g., native and stacked) in the accelerator to store activations and re-use them. The high-BW channel may also access activations from the stacked 3D SRAM. If the workload prefers weight stationary, the configuration may be set to use local SRAM as weight SRAM. The dynamic partition may also be performed at this stage to allocate the stacked SRAM to activations and weights, based on an optimal energy efficiency. This configuration may be performed at run time and on a per-workload basis. Performing the configuration in this manner may make the accelerator adaptable to different workload preferences to achieve the best overall performance and energy efficiency. Also, for workloads that require more memory (e.g., over 4 MB activation memory), three-die stacking may be used to provide more activation memory on-chip and to reduce the off-chip memory access.

As noted above, different configuration settings 600 and 650 may result in different partitions of memory for different types of data. For example, configuration setting 700 (e.g., configuration register=3′b011) may configure four megabytes of native and stacked activation SRAM, such as one megabyte of native SRAM 702 on the logic die 704 and three megabytes of stacked activation SRAM 706 on the memory die 708. With this configuration setting 700, weights may be streamed in with high BW access to the three megabytes of stacked activation SRAM 706 on the memory die 708.

Additionally, configuration setting 710 (e.g., configuration register=3′b010) may configure one megabyte of native activation SRAM 712 on the logic die 714, two megabytes of stacked activation SRAM 716 on the memory die 720, and one megabyte of stacked weight SRAM 718 on the memory die 720. This configuration setting 710 may provide high BW access to the two megabytes of stacked activation SRAM 716 on the memory die 720 and low BW access to the one megabyte of stacked weight SRAM 718 on the memory die 720.

Also, configuration setting 722 (e.g., configuration register=3′b001) may configure one megabyte of native activation SRAM 724 on the logic die 726, one megabyte of stacked activation SRAM 728 on the memory die 732, and two megabytes of stacked weight SRAM 730 on the memory die 732. This configuration setting 722 may provide high BW access to the one megabyte of stacked activation SRAM 728 on the memory die 732 and low BW access to the two megabytes of stacked weight SRAM 730 on the memory die 732.

Further, configuration setting 734 (e.g., configuration register=3′b000) may configure one megabyte of native activation SRAM 736 on the logic die 738 and three megabytes of stacked weight SRAM 740 on the memory die 742. This configuration setting 734 may provide low BW access to the three megabytes of stacked weight SRAM 740 on the memory die 742.

Still further, configuration setting 750 (e.g., configuration register=3′b111) may configure one megabyte of native weight SRAM 752 on the logic die 754 and three megabytes of stacked weight SRAM 756 on the memory die 758. This configuration setting 750 may provide low BW access to the three megabytes of stacked weight SRAM 756 on the memory die 758.

Further still, configuration setting 760 (e.g., configuration register=3′b110) may configure one megabyte of native weight SRAM 762 on the logic die 764, two megabytes of stacked activation SRAM 766 on the memory die 770, and one megabyte of stacked weight SRAM 768 on the memory die 770. This configuration setting 760 may provide high BW access to the two megabytes of stacked activation SRAM 766 on the memory die 770 and low BW access to the one megabyte of stacked weight SRAM 768 on the memory die 770.

Yet further, configuration setting 772 (e.g., configuration register=3′b101) may configure one megabyte of native weight SRAM 774 on the logic die 776, one megabyte of stacked activation SRAM 778 on the memory die 782, and two megabytes of stacked weight SRAM 780 on the memory die 782. This configuration setting 772 may provide low BW access to the two megabytes of stacked activation SRAM 780 on the memory die 782 and high BW access to the one megabyte of stacked weight SRAM 778 on the memory die 782.

Finally, configuration setting 784 (e.g., configuration register=3′b100) may configure one megabyte of native weight SRAM 786 on the logic die 788 and three megabytes of stacked activation SRAM 790 on the memory die 792. This configuration setting 784 may provide low BW access to the three megabytes of stacked activation SRAM 790 on the memory die 792.

The aforementioned example implementations may be combined in various ways that yield numerous benefits. For example, 3D stacked NN accelerator design that combines various features described above may achieve run-time adaptive workload partition and support large AR NN workloads with high energy efficiency and low latency. Since the 3D stacking may be performed through hybrid bonds, the latency through these 3D “wires” may be similar to latency through local wires. Meanwhile, since the bonds may be placed as top metal connections, no extra area is required, thus achieving increased SRAM capacity as iso-area.

### EXAMPLE EMBODIMENTS

Example 1: A semiconductor device may include a logic die including a circuit and a memory, and a memory die including an additional memory having a same footprint as the circuit and memory in the logic die, wherein the logic die and the memory die are stacked three-dimensionally with die-to-die data communication between the circuit and the additional memory by face-to-face hybrid bonds.

Example 2: The semiconductor device of Example 1, wherein the die-to-die data communication by the face-to-face hybrid bonds occurs by a first connection channel having a first bandwidth and a second connection channel having a second bandwidth lower than the first bandwidth.

Example 3: The semiconductor device of any of Examples 1 and 2, wherein accesses of the first connection channel and the second connection channel to memory banks of the additional memory are controlled by a configuration register that governs a partition of the additional memory.

Example 4: The semiconductor device of any of Examples 1 to 3, wherein the configuration register governs storage of data types in partitions of the additional memory.

Example 5: The semiconductor device of any of Examples 1 to 4, wherein the circuit corresponds to a processor of a neural network accelerator.

Example 6: The semiconductor device of any of Examples 1 to 5, wherein the configuration register triggers storage of weights in a first partition of the additional memory and storage of activations in a second partition of the additional memory.

Example 7: The semiconductor device of any of Examples 1 to 6, wherein the circuit is configured to set the configuration register to select the partition and two or more data types based on pre-profiled characteristics of a workload.

Example 8: The semiconductor device of any of Examples 1 to 7, wherein the second connection channel is connected to top input-output ports of the circuit through a protocol managed interface.

Example 9: The semiconductor device of any of Examples 1 to 8, wherein the first connection channel is connected to internal wires of the circuit through local three-dimensional wires.

Example 10: The semiconductor device of any of Examples 1 to 9, wherein the face-to-face hybrid bonds are positioned directly atop a macro of the additional memory.

Example 11: The semiconductor device of any of Examples 1 to 10, further including an additional memory die including a further memory having a same footprint as the circuit and memory in the logic die, wherein the logic die and the additional memory die are stacked three-dimensionally with die-to-die data communication between the circuit and the further memory by face-to-back through silicon via.

Example 12: A method may include providing a logic die including a circuit and a memory, providing a memory die including an additional memory having a same footprint as the circuit and memory in the logic die, and stacking the logic die and the memory die three-dimensionally with die-to-die data communication between the circuit and the additional memory by face-to-face hybrid bonds.

Example 13: The method of Example 12, wherein the die-to-die data communication by the face-to-face hybrid bonds occurs by a first connection channel having a first bandwidth and a second connection channel having a second bandwidth lower than the first bandwidth.

Example 14: The method of any of Examples 12 and 13, wherein accesses of the first connection channel and the second connection channel to memory banks of the additional memory are controlled by a configuration register that governs a partition of the additional memory, and the configuration register governs storage of data types in partitions of the additional memory.

Example 15: The method of any of Examples 12 to 14, wherein the circuit corresponds to a processor of a neural network accelerator, the configuration register triggers storage of weights in a first partition of the additional memory and storage of activations in a second partition of the additional memory.

Example 16: The method of any of Examples 12 to 15, wherein the circuit is configured to set the configuration register to select the partition and two or more data types based on pre-profiled characteristics of a workload.

Example 17: The method of any of Examples 12 to 16, wherein the second connection channel is connected to top input-output ports of the circuit through a protocol managed interface, the first connection channel is connected to internal wires of the circuit through local three-dimensional wires, and/or the face-to-face hybrid bonds are positioned directly atop a macro of the additional memory.

Example 18: The method of any of Examples 12 to 17, further including providing an additional memory die including a further memory having a same footprint as the circuit and memory in the logic die, and stacking the logic die and the additional memory die three-dimensionally with die-to-die data communication between the circuit and the further memory by face-to-back through silicon via.

Example 19: A system may include a display device and a neural network accelerator configured to process images rendered to the display device, wherein the neural network accelerator includes a logic die including a circuit and a memory, and a memory die including an additional memory having a same footprint as the circuit and memory in the logic die, and the logic die and the memory die are stacked three-dimensionally with die-to-die data communication between the circuit and the additional memory by face-to-face hybrid bonds.

Example 20: The system of Example 19, wherein the neural network accelerator further includes an additional memory die including a further memory having a same footprint as the circuit and memory in the logic die, and the logic die and the additional memory die are stacked three-dimensionally with die-to-die data communication between the circuit and the further memory by face-to-back through silicon via.

Embodiments of the present disclosure may include or be implemented in-conjunction with various types of artificial reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial reality systems may be designed to work without near-eye displays (NEDs). Other artificial reality systems may include an NED that also provides visibility into the real world (such as, e.g., augmented-reality system 800 in FIG. 8) or that visually immerses a user in an artificial reality (such as, e.g., virtual-reality system 900 in FIG. 9). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 8, augmented-reality system 800 may include an eyewear device 802 with a frame 810 configured to hold a left display device 815(A) and a right display device 815(B) in front of a user's eyes. Display devices 815(A) and 815(B) may act together or independently to present an image or series of images to a user. While augmented-reality system 800 includes two displays, embodiments of this disclosure may be implemented in augmented-reality systems with a single NED or more than two NEDs.

In some embodiments, augmented-reality system 800 may include one or more sensors, such as sensor 840. Sensor 840 may generate measurement signals in response to motion of augmented-reality system 800 and may be located on substantially any portion of frame 810. Sensor 840 may represent one or more of a variety of different sensing mechanisms, such as a position sensor, an inertial measurement unit (IMU), a depth camera assembly, a structured light emitter and/or detector, or any combination thereof. In some embodiments, augmented-reality system 800 may or may not include sensor 840 or may include more than one sensor. In embodiments in which sensor 840 includes an IMU, the IMU may generate calibration data based on measurement signals from sensor 840. Examples of sensor 840 may include, without limitation, accelerometers, gyroscopes, magnetometers, other suitable types of sensors that detect motion, sensors used for error correction of the IMU, or some combination thereof.

In some examples, augmented-reality system 800 may also include a microphone array with a plurality of acoustic transducers 820(A)-820(J), referred to collectively as acoustic transducers 820. Acoustic transducers 820 may represent transducers that detect air pressure variations induced by sound waves. Each acoustic transducer 820 may be configured to detect sound and convert the detected sound into an electronic format (e.g., an analog or digital format). The microphone array in FIG. 8 may include, for example, ten acoustic transducers: 820(A) and 820(B), which may be designed to be placed inside a corresponding ear of the user, acoustic transducers 820(C), 820(D), 820(E), 820(F), 820(G), and 820(H), which may be positioned at various locations on frame 810, and/or acoustic transducers 820(I) and 820(J), which may be positioned on a corresponding neckband 805.

In some embodiments, one or more of acoustic transducers 820(A)-(J) may be used as output transducers (e.g., speakers). For example, acoustic transducers 820(A) and/or 820(B) may be earbuds or any other suitable type of headphone or speaker.

The configuration of acoustic transducers 820 of the microphone array may vary. While augmented-reality system 800 is shown in FIG. 8 as having ten acoustic transducers 820, the number of acoustic transducers 820 may be greater or less than ten. In some embodiments, using higher numbers of acoustic transducers 820 may increase the amount of audio information collected and/or the sensitivity and accuracy of the audio information. In contrast, using a lower number of acoustic transducers 820 may decrease the computing power required by an associated controller 850 to process the collected audio information. In addition, the position of each acoustic transducer 820 of the microphone array may vary. For example, the position of an acoustic transducer 820 may include a defined position on the user, a defined coordinate on frame 810, an orientation associated with each acoustic transducer 820, or some combination thereof.

Acoustic transducers 820(A) and 820(B) may be positioned on different parts of the user's ear, such as behind the pinna, behind the tragus, and/or within the auricle or fossa. Or, there may be additional acoustic transducers 820 on or surrounding the ear in addition to acoustic transducers 820 inside the ear canal. Having an acoustic transducer 820 positioned next to an ear canal of a user may enable the microphone array to collect information on how sounds arrive at the ear canal. By positioning at least two of acoustic transducers 820 on either side of a user's head (e.g., as binaural microphones), augmented-reality system 800 may simulate binaural hearing and capture a 3D stereo sound field around about a user's head. In some embodiments, acoustic transducers 820(A) and 820(B) may be connected to augmented-reality system 800 via a wired connection 830, and in other embodiments acoustic transducers 820(A) and 820(B) may be connected to augmented-reality system 800 via a wireless connection (e.g., a BLUETOOTH connection). In still other embodiments, acoustic transducers 820(A) and 820(B) may not be used at all in conjunction with augmented-reality system 800.

Acoustic transducers 820 on frame 810 may be positioned in a variety of different ways, including along the length of the temples, across the bridge, above or below display devices 815(A) and 815(B), or some combination thereof. Acoustic transducers 820 may also be oriented such that the microphone array is able to detect sounds in a wide range of directions surrounding the user wearing the augmented-reality system 800. In some embodiments, an optimization process may be performed during manufacturing of augmented-reality system 800 to determine relative positioning of each acoustic transducer 820 in the microphone array.

In some examples, augmented-reality system 800 may include or be connected to an external device (e.g., a paired device), such as neckband 805. Neckband 805 generally represents any type or form of paired device. Thus, the following discussion of neckband 805 may also apply to various other paired devices, such as charging cases, smart watches, smart phones, wrist bands, other wearable devices, hand-held controllers, tablet computers, laptop computers, other external compute devices, etc.

As shown, neckband 805 may be coupled to eyewear device 802 via one or more connectors. The connectors may be wired or wireless and may include electrical and/or non-electrical (e.g., structural) components. In some cases, eyewear device 802 and neckband 805 may operate independently without any wired or wireless connection between them. While FIG. 8 illustrates the components of eyewear device 802 and neckband 805 in example locations on eyewear device 802 and neckband 805, the components may be located elsewhere and/or distributed differently on eyewear device 802 and/or neckband 805. In some embodiments, the components of eyewear device 802 and neckband 805 may be located on one or more additional peripheral devices paired with eyewear device 802, neckband 805, or some combination thereof.

Pairing external devices, such as neckband 805, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 800 may be provided by a paired device or shared between a paired device and an eyewear device, thus reducing the weight, heat profile, and form factor of the eyewear device overall while still retaining desired functionality. For example, neckband 805 may allow components that would otherwise be included on an eyewear device to be included in neckband 805 since users may tolerate a heavier weight load on their shoulders than they would tolerate on their heads. Neckband 805 may also have a larger surface area over which to diffuse and disperse heat to the ambient environment. Thus, neckband 805 may allow for greater battery and computation capacity than might otherwise have been possible on a stand-alone eyewear device. Since weight carried in neckband 805 may be less invasive to a user than weight carried in eyewear device 802, a user may tolerate wearing a lighter eyewear device and carrying or wearing the paired device for greater lengths of time than a user would tolerate wearing a heavy standalone eyewear device, thereby enabling users to more fully incorporate artificial reality environments into their day-to-day activities.

Neckband 805 may be communicatively coupled with eyewear device 802 and/or to other devices. These other devices may provide certain functions (e.g., tracking, localizing, depth mapping, processing, storage, etc.) to augmented-reality system 800. In the embodiment of FIG. 8, neckband 805 may include two acoustic transducers (e.g., 820(I) and 820(J)) that are part of the microphone array (or potentially form their own microphone subarray). Neckband 805 may also include a controller 825 and a power source 835.

Acoustic transducers 820(I) and 820(J) of neckband 805 may be configured to detect sound and convert the detected sound into an electronic format (analog or digital). In the embodiment of FIG. 8, acoustic transducers 820(I) and 820(J) may be positioned on neckband 805, thereby increasing the distance between the neckband acoustic transducers 820(I) and 820(J) and other acoustic transducers 820 positioned on eyewear device 802. In some cases, increasing the distance between acoustic transducers 820 of the microphone array may improve the accuracy of beamforming performed via the microphone array. For example, if a sound is detected by acoustic transducers 820(C) and 820(D) and the distance between acoustic transducers 820(C) and 820(D) is greater than, e.g., the distance between acoustic transducers 820(D) and 820(E), the determined source location of the detected sound may be more accurate than if the sound had been detected by acoustic transducers 820(D) and 820(E).

Controller 825 of neckband 805 may process information generated by the sensors on neckband 805 and/or augmented-reality system 800. For example, controller 825 may process information from the microphone array that describes sounds detected by the microphone array. For each detected sound, controller 825 may perform a direction-of-arrival (DOA) estimation to estimate a direction from which the detected sound arrived at the microphone array. As the microphone array detects sounds, controller 825 may populate an audio data set with the information. In embodiments in which augmented-reality system 800 includes an inertial measurement unit, controller 825 may compute all inertial and spatial calculations from the IMU located on eyewear device 802. A connector may convey information between augmented-reality system 800 and neckband 805 and between augmented-reality system 800 and controller 825. The information may be in the form of optical data, electrical data, wireless data, or any other transmittable data form. Moving the processing of information generated by augmented-reality system 800 to neckband 805 may reduce weight and heat in eyewear device 802, making it more comfortable to the user.

Power source 835 in neckband 805 may provide power to eyewear device 802 and/or to neckband 805. Power source 835 may include, without limitation, lithium-ion batteries, lithium-polymer batteries, primary lithium batteries, alkaline batteries, or any other form of power storage. In some cases, power source 835 may be a wired power source. Including power source 835 on neckband 805 instead of on eyewear device 802 may help better distribute the weight and heat generated by power source 835.

As noted, some artificial reality systems may, instead of blending an artificial reality with actual reality, substantially replace one or more of a user's sensory perceptions of the real world with a virtual experience. One example of this type of system is a head-worn display system, such as virtual-reality system 900 in FIG. 9, that mostly or completely covers a user's field of view. Virtual-reality system 900 may include a front rigid body 902 and a band 904 shaped to fit around a user's head. Virtual-reality system 900 may also include output audio transducers 906(A) and 906(B). Furthermore, while not shown in FIG. 9, front rigid body 902 may include one or more electronic elements, including one or more electronic displays, one or more inertial measurement units (IMUs), one or more tracking emitters or detectors, and/or any other suitable device or system for creating an artificial-reality experience.

Artificial reality systems may include a variety of types of visual feedback mechanisms. For example, display devices in augmented-reality system 800 and/or virtual-reality system 900 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial reality systems may include a single display screen for both eyes or may provide a display screen for each eye, which may allow for additional flexibility for varifocal adjustments or for correcting a user's refractive error. Some of these artificial reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial reality systems described herein may include one or more projection systems. For example, display devices in augmented-reality system 800 and/or virtual-reality system 900 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial reality systems may also be configured with any other suitable type or form of image projection system, such as retinal projectors used in virtual retina displays.

The artificial reality systems described herein may also include various types of computer vision components and subsystems. For example, augmented-reality system 800 and/or virtual-reality system 900 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial reality system may process data from one or more of these sensors to identify a location of a user, to map the real world, to provide a user with context about real-world surroundings, and/or to perform a variety of other functions.

The artificial reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial reality devices, within other artificial reality devices, and/or in conjunction with other artificial reality devices.

By providing haptic sensations, audible content, and/or visual content, artificial reality systems may create an entire virtual experience or enhance a user's real-world experience in a variety of contexts and environments. For instance, artificial reality systems may assist or extend a user's perception, memory, or cognition within a particular environment. Some systems may enhance a user's interactions with other people in the real world or may enable more immersive interactions with other people in a virtual world. Artificial reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial reality experience in one or more of these contexts and environments and/or in other contexts and environments.

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A semiconductor device comprising:
a logic die including a circuit and a memory; and
a memory die including an additional memory having a same footprint as the circuit and memory in the logic die,
wherein the logic die and the memory die are stacked three-dimensionally with die-to-die data communication between the circuit and the additional memory by face-to-face hybrid bonds.

2. The semiconductor device of claim 1, wherein the die-to-die data communication by the face-to-face hybrid bonds occurs by a first connection channel having a first bandwidth and a second connection channel having a second bandwidth lower than the first bandwidth.

3. The semiconductor device of claim 2, wherein accesses of the first connection channel and the second connection channel to memory banks of the additional memory are controlled by a configuration register that governs a partition of the additional memory.

4. The semiconductor device of claim 3, wherein the configuration register governs storage of data types in partitions of the additional memory.

5. The semiconductor device of claim 4, wherein the circuit corresponds to a processor of a neural network accelerator.

6. The semiconductor device of claim 5, wherein the configuration register triggers storage of weights in a first partition of the additional memory and storage of activations in a second partition of the additional memory.

7. The semiconductor device of claim 4, wherein the circuit is configured to set the configuration register to select the partition and two or more data types based on pre-profiled characteristics of a workload.

8. The semiconductor device of claim 2, wherein the second connection channel is connected to top input-output ports of the circuit through a protocol managed interface.

9. The semiconductor device of claim 2, wherein the first connection channel is connected to internal wires of the circuit through local three-dimensional wires.

10. The semiconductor device of claim 1, wherein the face-to-face hybrid bonds are positioned directly atop a macro of the additional memory.

11. The semiconductor device of claim 1, further comprising:
an additional memory die including a further memory having a same footprint as the circuit and memory in the logic die,
wherein the logic die and the additional memory die are stacked three-dimensionally with die-to-die data communication between the circuit and the further memory by face-to-back through silicon via.

12. A method comprising:
providing a logic die including a circuit and a memory;
providing a memory die including an additional memory having a same footprint as the circuit and memory in the logic die; and
stacking the logic die and the memory die three-dimensionally with die-to-die data communication between the circuit and the additional memory by face-to-face hybrid bonds.

13. The method of claim 12, wherein the die-to-die data communication by the face-to-face hybrid bonds occurs by a first connection channel having a first bandwidth and a second connection channel having a second bandwidth lower than the first bandwidth.

14. The method of claim 13, wherein accesses of the first connection channel and the second connection channel to memory banks of the additional memory are controlled by a configuration register that governs a partition of the additional memory, and the configuration register governs storage of data types in partitions of the additional memory.

15. The method of claim 14, wherein the circuit corresponds to a processor of a neural network accelerator, the configuration register triggers storage of weights in a first partition of the additional memory and storage of activations in a second partition of the additional memory.

16. The method of claim 14, wherein the circuit is configured to set the configuration register to select the partition and two or more data types based on pre-profiled characteristics of a workload.

17. The method of claim 13, wherein at least one of:
the second connection channel is connected to top input-output ports of the circuit through a protocol managed interface;
the first connection channel is connected to internal wires of the circuit through local three-dimensional wires; or
the face-to-face hybrid bonds are positioned directly atop a macro of the additional memory.

18. The method of claim 12, further comprising:
providing an additional memory die including a further memory having a same footprint as the circuit and memory in the logic die; and
stacking the logic die and the additional memory die three-dimensionally with die-to-die data communication between the circuit and the further memory by face-to-back through silicon via.

19. A system comprising:
a display device; and
a neural network accelerator configured to process images rendered to the display device, wherein the neural network accelerator includes:
a logic die including a circuit and a memory; and
a memory die including an additional memory having a same footprint as the circuit and memory in the logic die,
wherein the logic die and the memory die are stacked three-dimensionally with die-to-die data communication between the circuit and the additional memory by face-to-face hybrid bonds.

20. The system of claim 19, wherein the neural network accelerator further includes:
an additional memory die including a further memory having a same footprint as the circuit and memory in the logic die,
wherein the logic die and the additional memory die are stacked three-dimensionally with die-to-die data communication between the circuit and the further memory by face-to-back through silicon via.
